(19) United States
(12) Patent Application Publication
(10) Pub. No.: US 2006/0256518 A1
(43) Pub. Date: Nov. 16, 2006

(54) Structure and method of a data processing product with anion function

(76) Inventor: Long-Kun Yu, Taipei Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/128,274

(22) Filed: May 13, 2005

(51) Int. Cl. H05K 7/20

(52) U.S. Cl. 361/687

(57) ABSTRACT

A structure and method for a data processing product with anion function, in which the structure provides a anions apparatus comprising of an apparatus housing for assembling various storage media of the data processing product. There are air-exhaust portions and air-entrance portions arranged in the front side and the rear side of the apparatus housing. The air-entrance portions have an air actuator and the power supply for the data processing product is electrically connected with the anions apparatus for supplying power. A method for data processing product with anion function for applying an anions module to a data processing product comprises designing an assembly place in a convective scope between the air actuator and the air holes, assembling the anions module in the assembly place, and connecting power supply for the data processing product with the anions module.

### BACKGROUND OF THE INVENTION

1. Field of the Invention

The present invention relates to a structure and method for a data processing product with anion function, and more particularly to a structure and method for a data processing product that outputs air with a great quantity of anions.

2. Description of Related Art

Anions are formed when atoms gain electrons. For example, an atom with a positive electric charge is called a positive ion; an atom with a negative electric charge is called a negative ion.

While improvements have been made in some areas of reducing air pollution, such as the lowering of emissions of, sulfur dioxide (SO2), nitrogen dioxide (NO2) and ozone (O3), air pollution, particularly in the form of particulates, remains a serious health problem for many parts of the globe. In addition to damaging the lungs and heart, air pollution is now recognized as being especially harmful to children, the elderly, and selective sensitive people, such as those afflicted with diabetes, cardiopulmonary diseases or other debilitating illnesses.

Anions have long been attributed to improvements in mood and physical health.

The Taiwan Patent TW574926 disclosed a anions generator that generated a high voltage via a piezoelectric transformer, the high voltage being further increased via a multi-stage multiplication circuit to produce a large amount of anions.

However, the anions generator is only used independently. It is not combined with any other apparatus in order to save space. Additionally, because there aren't any fans disposed in the anions generator, the direction of the flow of the anions is dependent on airflow.

Hence, the anions apparatus is suitable to be used by a computer user who uses a data processing product (such as a desktop computer, a notebook computer, or a portable computer) for long time periods. Because these data processing products have heat-dissipated fans, that are suitable for being used to drive anions, they can provide the environment with a large amount of anions for a user using a data processing product over long time periods.

The inventor of the present invention recognizes the above deficiency should be corrected and special effort has been paid to research this field. The present invention is presented with reasonable design and good effect to resolve the above problems.

### SUMMARY OF THE INVENTION

It is a first objective of the present invention to provide a anions apparatus which effectively matches with a data processing product for improving the amalgamation of the two products.

It is a second objective of the present invention to provide an environment with a large amount of anions for a user using a data processing product for long time periods.

It is third objective of the present invention to provide an efficiently designed space so that air with a large amount of anions is outputted by means of active convective airflow.

For achieving the objectives stated above, an anions apparatus comprises an apparatus housing, at least one air actuator, and at least one anions module. The apparatus housing has a first side with an air-exhaust portion and a second side with an air-entrance portion. The air actuator is disposed in the apparatus housing and communicated with either the air-exhaust portion or the air-entrance portion, or a combination of the all of the devices. The anions module disposed between the first side and the second side of the apparatus housing and the anions module and the air actuator are electrically connected with the data processing product.

The present invention further provides a data processing product with a anion function, comprising of a host body, a motherboard, at least one anions module, and at least one air actuator. The host body is a data processing product with a plurality of air holes, the motherboard is disposed in the host body, and the anions module is disposed on the motherboard and electrically connects with the motherboard. The air actuator is disposed in the host body and is electrically connected with the data processing product, the air actuator and the holes of the host body thereby creating a convective airflow.

The present invention further provides an anions motherboard applied to a host body of a data processing product with a plurality of air holes. The motherboard comprises at least an anions module and at least an air actuator. The anions module is disposed on the motherboard and electrically connects with the motherboard, the air actuator is disposed on the motherboard and electrically connects with the motherboard; the air actuator and the holes of the host body cause convective airflow.

The present invention provides a method for a data processing product with anion function for applying an anions module to a data processing product. The data processing product has at least one air actuator and a plurality of air holes, and comprises of the following steps:

designing an assembled place in a convective scope between the air actuator and the air holes;

assembling the anions module in the assembled place; and

connecting a power source of the data processing product with the anions module.

The present invention further provides a method for a data processing product with anion function for applying an anions module to a data processing product, which comprises of the following steps:

designing an assembly portion to a side of the data processing product;

designing a shell with active convective air-entrance portions and air-exhaust portions on two relative sides of the shell;

assembling the anions module between the air-entrance portion and the air-exhaust portion of the shell;

assembling the shell in the assembly portion; and

connecting a power source of the data processing product with the shell.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

FIG. 1 is a schematic view showing the first embodiment according to the present invention;

FIG. 1A is a partial enlarged view of FIG. 1;

FIG. 2 is a schematic view showing the second embodiment according to the present invention;

FIG. 3 is a schematic view showing the third embodiment according to the present invention;

FIG. 4 is a schematic view showing the fourth embodiment according to the present invention;

FIG. 5 is a schematic view showing the fifth embodiment according to the present invention; and

FIG. 6 is a schematic view showing the sixth embodiment according to the present invention;

### DETAILED DESCRIPTION OF THE PREFERRED EMBODIMENTS

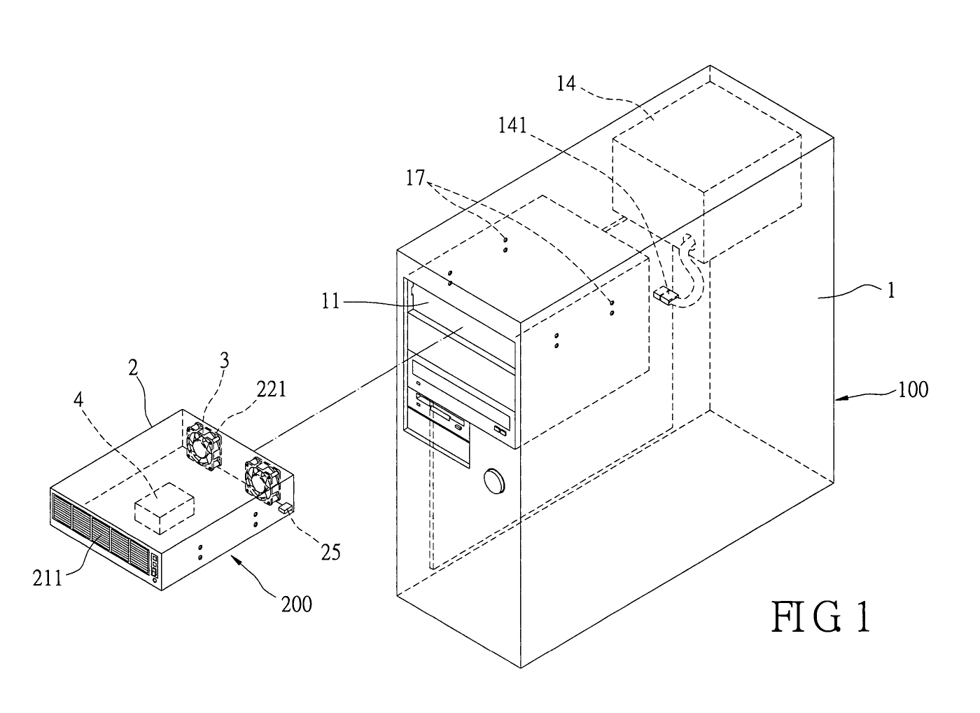

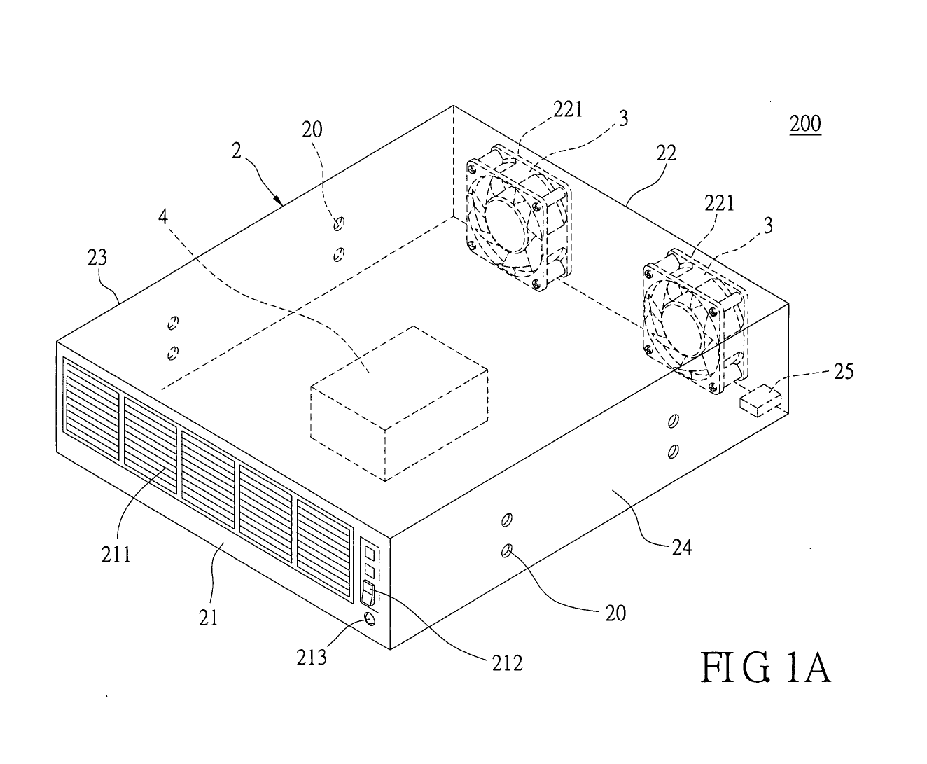

Reference is made to FIG. 1 to FIG. 6. The present invention provides a structure and method for a data processing product with anion function, and the first embodiment to the sixth embodiment are separately disclosed in FIG. 1 to FIG. 6.

Reference is made to FIG. 1 and FIG. 1A which disclose a anions apparatus 200 applied to a data processing product 100, wherein the data processing product 100 is a desktop computer, a notebook computer, a portable computer, or a similar product for executing data processing.

The anions apparatus 200 comprises an apparatus housing 2, at least one air actuator 3, and a negative irons module 4. The apparatus housing 2 has a first side 21, a second side 22, a third side 23, and a fourth side 24, thereby the first side 21 has an air-exhaust portion 211 and the second side 22 has an air-entrance portion or at least one air-entrance portion 221. The air actuator 3 can be an axial fan, a vortex fan, a radiation fan or any other similar device. The at least one air actuator 3 is disposed in the air-entrance portion 221 of the apparatus housing 2, so that the air actuator 3 can communicate with the air-entrance portion 221 for leading external are into the air actuator 3. The air actuator 3 is also connected with either the air-exhaust portion 211 or the air-entrance portion 221, or a combination of all of the devices. The anions module 4 has a basic function like the conventional anions generator to ionize the air by means of the high voltage electrostatic field to generate a large amount of the anions. The anions module 4 is disposed in the apparatus housing 2 and is disposed between the first side 21 and the second side 22 to carry the anions via the airflow. Furthermore, the anions module 4 and the air actuator 3 are electrically connected with the data processing product 100 for supplying power.

The anions apparatus 200 is disposed in an assembly portion 11 and the apparatus housing 2 of the anions apparatus 200 has a third side 23 and the fourth side 24 opposite to the third side 23 has a plurality of fixed holes 20. The data processing product 100 has a plurality of assembled spaces for assembling various storage media, each inner wall of the assembled spaces has a plurality of holes 17 and one of the assembled spaces is an assembly portion 11; each fixed hole 20 of the apparatus housing is relative to each hole 17 for positioning. The first side 21 with a plurality of air-exhaust portions 211 is exposed to the outside of the assembly portion 11 to carry a large amount of anions to a user who uses a data processing product 100 for a long period of time.

It is worthy to note that the assembly portion 11 of the data processing product 100 is originally one of the various assembled spaces. An example of a personal computer, the assembly portion 11 is originally one of the various assembly spaces (for assembling an optical disk drive or a CD-RW optical drive, or so on). Hence, users only need to directly assemble the anions apparatus 200 by assembling the various storage media without changing the design of the data processing product 100.

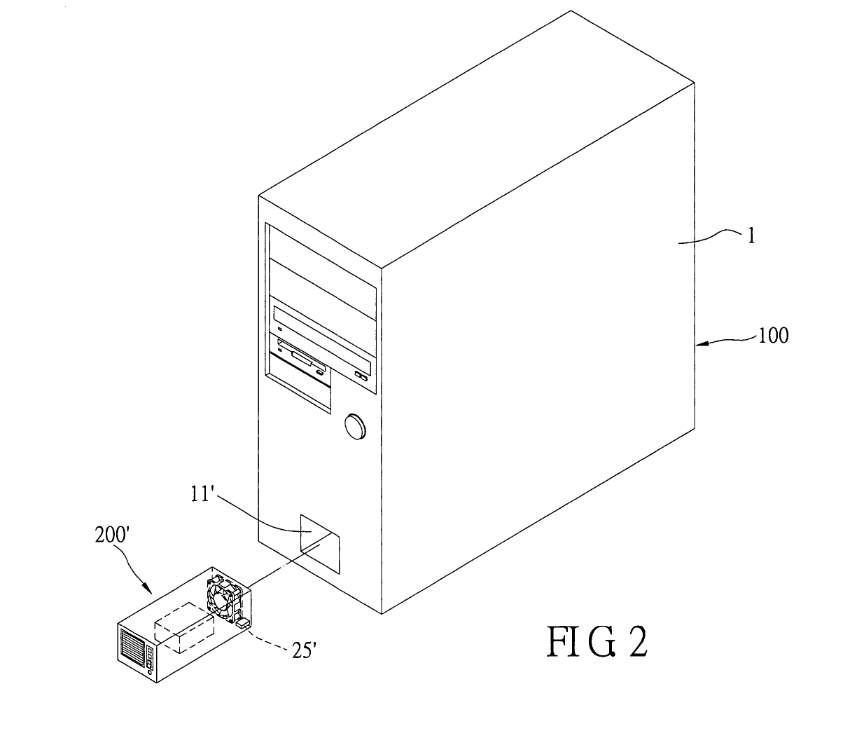

Reference is made to FIG. 2 disclosing another anions apparatus 200′ applied to a data processing product 100. The data processing product 100 further has an assembly portion 11′ relative to the anions apparatus 200′ for making assembly more convenient. The assembly portion 11′ is electrically connected to the data processing product 100 for supplying power. Furthermore, the structure of the anions apparatus 200′ of the second embodiment is similar to the anions apparatus 200, but the appearance, the outline or the size is different.

Each apparatus housing of the anions apparatus 200 or 200′ of the present invention further separately has a butt-joint power connector 25 or 25′, and the data processing product 100 has a power connector 141 mutually connected with the butt-joint power connector 25 or 25′ for supplying power. Thereby, the power connector 141 can be one of the power connectors of the power supply 14, or it can be added additionally.

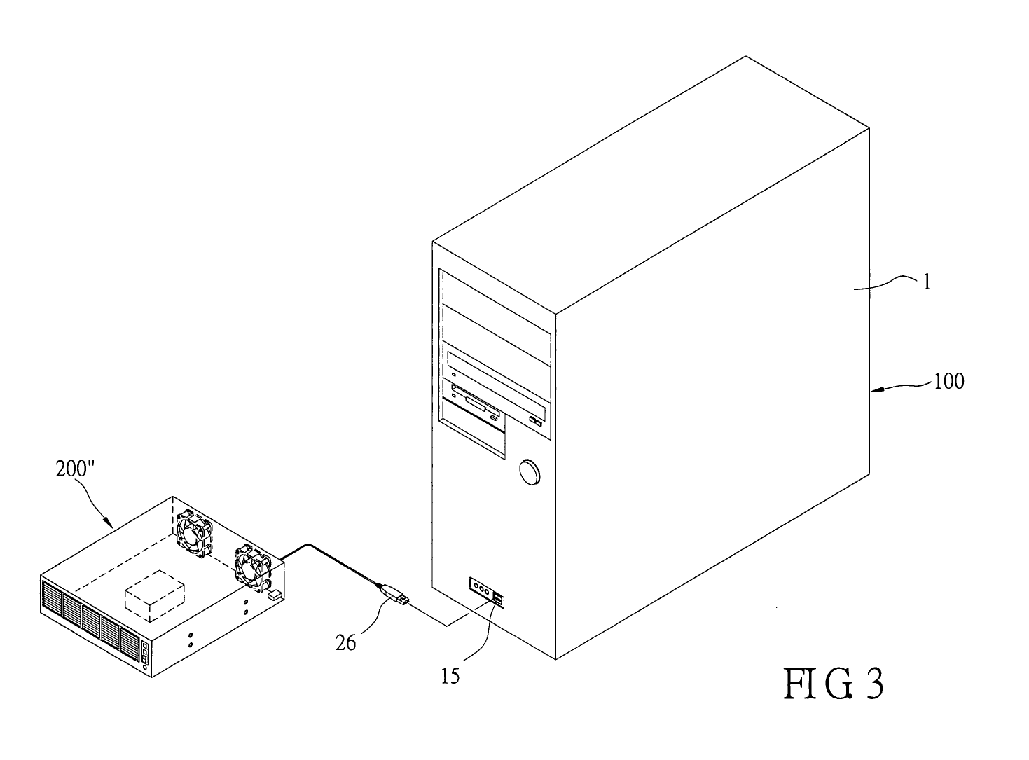

Reference is made to FIG. 3 that discloses another anions apparatus 200″ applied to a data processing product 100. The structure of the anions apparatus 200″ is similar to the anions apparatus 200 and anions apparatus 200′ but the anions apparatus 200″ has an electric connector 26 without a butt-joint power connector 25 or a butt-joint power connector 25′. The electric connector 26 is electrically plugged into the butt-joint connector 15 of the data processing product 100 so that the anions apparatus 200″ externally connects to the data processing product 100. Furthermore, the electric connector 26 is also a universal serial bus (USB) for supplying power to the anions apparatus 200″.

Each apparatus housing of the anions appearances 200, 200′ or 200″ of the present invention further separately has a control switch is easy to operate. Reference is made to FIG. 1 and FIG. 1A, in which the first side 21 of the apparatus housing 2 has at least one switch 212. Each of the switches 212 are separately electrically connected with the anions module 4 and the air actuator 3 for individually starting the anions module 4 or the air actuator 3. Alternatively, the at least one switch 212 can be electrically connected with the anions module 4 and the air actuator 3 for collectively starting the anions module 4 or the air actuator 3. Furthermore, the first side 21 of the apparatus housing 2 further has a display light 213 for displaying the ON/OFF status of the anions module 4, the air actuator 3, or their combination.

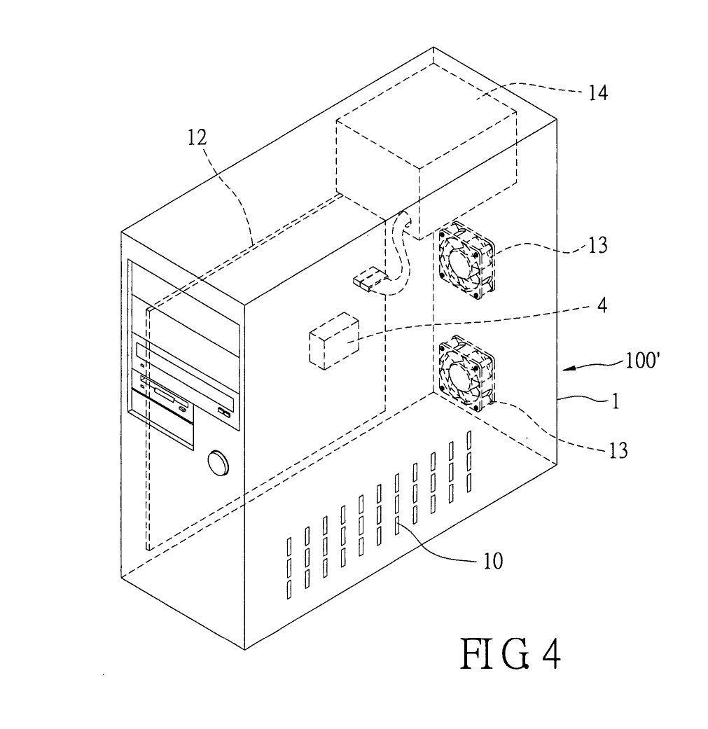

Reference is made to FIG. 4 that discloses a structure and method for a data processing product with anion function. A data processing product 100′ has a host body 1, a motherboard 12 disposed in the host body 1, at least one air actuator 13 disposed in the host body 1, and at least one anions module 4 disposed on the motherboard 12. Thereby, the host body 1 has a plurality of air holes 10. The anions module 4 further electrically connects with the motherboard 12. The air actuator 13 and the holes 10 of the host body 1 cause a convective airflow and a power supply 14 for the data processing product 100′ supplies power to the motherboard 12 and the air actuator 13.

After users turn on the data processing product 100′, the anions module 4 is also turned on. The holes 10 carry a large amount of anions to a user who uses the data processing product 100′ for long periods of time by means of the air actuator 13 and the holes 10 of the data processing product 100′ that create a convective airflow.

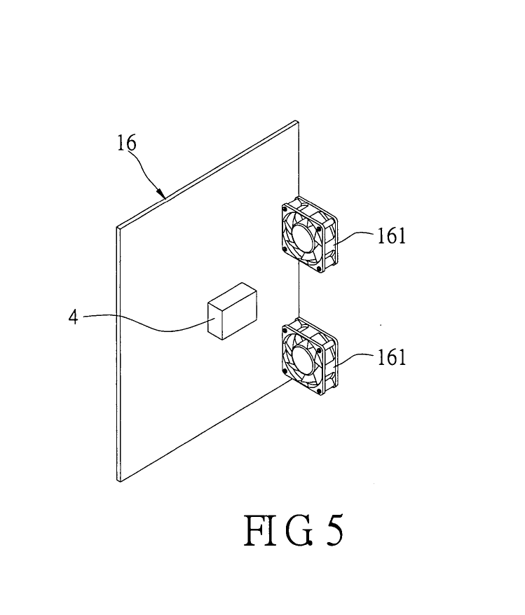

Reference is made to FIG. 5 that discloses an anions motherboard applied to a host body of a data processing product. The host body has a plurality of air holes (the data processing product, host body, and air holes are shown in FIG. 4), the motherboard 16 has at least one anions module 4 and at least one air actuator 161. The anions module 4 is disposed on the motherboard 16 and electrically connects with the motherboard 16, the air actuator 161 is also disposed on the motherboard 16 and electrically connects with the motherboard 16. The air actuator 161 and the holes of the host body create a convective airflow. Hence, after users turn on the data processing product, the anions module 4 begins to have the same function as the fourth embodiment. Moreover, the interaction of the air actuator 161 and the air actuator of the host body creates a superior convective airflow to carry more anions.

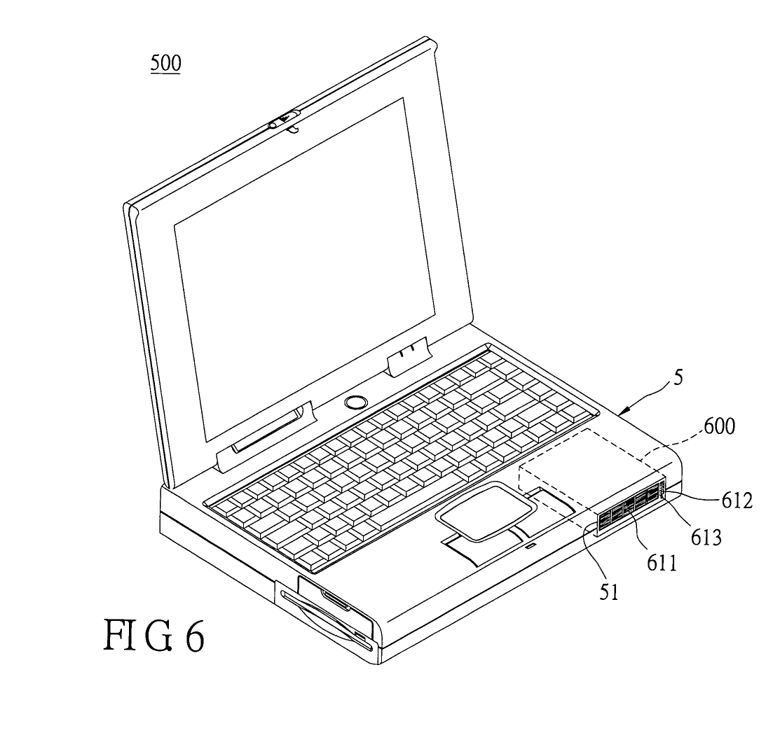

Reference is made to FIG. 6 that discloses another anions apparatus 600 applied to a data processing product 500. The data processing product 500 can be a notebook computer or a portable computer. The anions apparatus 600 is disposed in an assembly portion 51 of a host body 5 of the data processing product 500. The assembly portion 51 is one of the assembled spaces of the data processing product 500 for assembling various storage media. After the anions apparatus 600 is disposed, one side of the anions apparatus 600 is exposed to the outside of the host body 5 and there are air-exhaust portions 611, switches 612, and display lights 613 arranged on the side.

In the first method for data processing product with a anion function for applying a anions module to a data processing product, the data processing product has at least one air actuator and a plurality of air holes comprising of the steps of:

designing an assembly place in a convective scope between the air actuator and the air holes;

assembling the anions module in the assembly place; and

connecting a power supply for the data processing product with the anions module. The fourth embodiment of the present invention is achieved by means of the first method of the present invention.

The second method for a data processing product with anion function for applying a anions module to a data processing product, comprises of the following steps:

designing an assembly portion to a side of the data processing product;

designing a shell with active convective air-entrance portions and air-exhaust portions on two relative sides of the shell;

assembling the anions module between the air-entrance portion and the air-exhaust portion of the shell; assembling the shell in the assembly portion; and

connecting a power supply for the data processing product with the shell.

Thereby, the air-entrance portion of the shell has at least one air actuator, the air-exhaust portion of the shell is exposed to the outside of the assembly portion. The shell has a butt-joint power connector; the data processing product has a power connector mutually connected with the butt-joint power connector for supplying power. The second embodiment of the present invention is achieved by means of the second method of the present invention.

Although the present invention has been described with reference to the preferred embodiment thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A anions apparatus applied to a data processing product, comprising:
an apparatus housing with a first side with an air-exhaust portion and a second side with an air-entrance portion;
at least one air actuator disposed in the apparatus housing and communicated with either the air-exhaust portion or the air-entrance portion, or a combination of the air-exhaust portion and the air-entrance portion; and
at least one anions module disposed between the first side and the second side of the apparatus housing; the anions module and the air actuator are electrically connected with the data processing product.

2. The anions apparatus as in claim 1, wherein the apparatus housing has a switch electrically connected with the anions module and the air actuator.

3. The anions apparatus as in claim 1, wherein the apparatus housing has two switches and each of the switches is electrically connected separately with the anions module and the air actuator.

4. The anions apparatus as in claim 1, wherein the apparatus housing further has a display light displaying the ON/OFF status of the anions apparatus.

5. The anions apparatus as in claim 1, wherein the air actuator is a fan.

6. The anions apparatus as in claim 1, wherein the apparatus housing further has a butt-joint power connector; the data processing product has a power connector mutually connected with the butt-joint power connector for supplying power.

7. The anions apparatus as in claim 6, wherein the first side of the apparatus housing has said switches; the data processing product has an assembly portion and the anions apparatus is disposed in the assembly portion, and the first side of the apparatus housing faces outside.

8. The anions apparatus as in claim 7, wherein the apparatus housing further has a third side and a fourth side disposed to each other, and each of the third side and the fourth side separately has a plurality of fixed holes; the data processing product has a plurality of assembled spaces for assembling various storage media, each inner wall of the assembled spaces has a plurality of holes and one of the assembled spaces is an assembled portion; each fixed hole of the apparatus housing is relative to each hole of the assembly portion for positioning.

9. The anions apparatus as in claim 1, wherein the apparatus housing electrically connects with an electric connector, the data processing product has a butt-joint connector; the electric connector electrically plugs into the butt-joint connector; the anions apparatus is connected outside of the data processing product.

10. The anions apparatus as in claim 9, wherein the electric connector is a universal serial bus (USB).

11. A data processing product with anions function, comprising:
a host body with a plurality of air holes;
a motherboard disposed in the host body;
at least one anions module disposed on the motherboard and electrically connected with the motherboard; and
at least one air actuator disposed in the host body and electrically connected with the data processing product, the air actuator and the holes of the host body create a convective airflow.

12. The data processing product with anions function as in claim 11, wherein the air actuator is a fan.

13. A anions motherboard applied to a host body of a data processing product with a plurality of air holes, comprising:
at least a anions module disposed on the motherboard and electrically connects with the motherboard; and
at least one air actuator disposed in the host body and electrically connected with the data processing product, the air actuator and the holes of the host body cause a convective airflow.

14. The anions motherboard as in claim 13, wherein the air actuator is a fan.

15. The anions motherboard as in claim 13, wherein the anions module is disposed in a convective scope between the air actuator and the air holes.

16. A method for a data processing product with anion function for applying a anions module to a data processing product, the data processing product has at least one air actuator and a plurality of air holes; comprising:
designing an assembly place in a convective scope between the air actuator and the air holes;
assembling the anions module in the assembly place; and
connecting a power supply for the data processing product with the anions module.

17. The method for a data processing product as in claim 16, wherein the data processing product has a motherboard and the assembly place is designed thereon.

18. A method for a data processing product with anion function for applying a anions module to a data processing product, comprising:
designing an assembly portion to a side of the data processing product;
designing a shell with active convective air-entrance portions and air-exhaust portions on two relative sides of the shell;
assembling the anions module between the air-entrance portion and the air-exhaust portion of the shell;
assembling the shell in the assembly portion; and
connecting a power supply for the data processing product with the shell.

19. The method of data processing product as in claim 18, wherein the assembly portion is one of the assembly spaces for the data processing product for assembling various storage media.

20. The method of data processing product as in claim 18, wherein the shell has at least one air actuator and the air actuators are connected with the air-entrance portion, the air-exhaust portion, or a combination of the air-entrance portion and the air-exhaust portion.

21. The method for a data processing product as in claim 18, wherein the air-exhaust portion of the shell is exposed to the outside of the assembly portion.

22. The method for a data processing product as in claim 18, wherein the shell has a butt-joint power connector; the data processing product has a power connector mutually connected with the butt-joint power connector for supplying power.
